(19) United States
(12) Patent Application Publication
(10) Pub. No.: US 2007/0040709 A1
(43) Pub. Date: Feb. 22, 2007

(54) Scalable audio encoding and/or decoding method and apparatus

(76) Inventors: Hosang Sung, Yongin-si (KR); Rakesh Taori, Suwon-si (KR); Kangeun Lee, Gangneung-si (KR); Shihwa Lee, Seoul (KR); Sangwook Kim, Seoul (KR); Miyoung Kim, Suwon-si (KR); Dohyung Kim, Hwaseong-si (KR)

Correspondence Address: STANZIONE & KIM, LLP, 919 18TH STREET, N.W., SUITE 440, WASHINGTON, DC, 20006, US

(21) Appl. No.: 11/485,468

(22) Filed: Jul. 13, 2006

(30) Foreign Application Priority Data
Jul. 13, 2005 (KR) 2005-63303
Jul. 11, 2006 (KR) 2006-64694

(51) Int. Cl. H03M 7/00

(52) U.S. Cl. 341/50

(57) ABSTRACT

A method and apparatus to scalably encode and/or decode an audio signal includes encoding a specific band signal included in an input signal, encoding a frequency envelope of an excited signal in which the encoded specific band signal is removed from the input signal, encoding a residual signal in which the encoded frequency envelope is removed from the excited signal, and forming a bit-stream by scalably packing the encoded specific band signal, frequency envelop, and residual signal.

### CROSS-REFERENCE TO RELATED APPLICATIONS

This application claims priority under 35 U.S.C. §119(a) from Korean Patent Applications No. 10-2005-0063303, filed on Jul. 13, 2005, and No. 10-2006-0064694, filed on Jul. 11, 2006 in the Korean Intellectual Property Office, the disclosures of which are incorporated herein in their entirety by reference.

### BACKGROUND OF THE INVENTION

1. Field of the Invention

The present general inventive concept relates to a scalable audio encoding and/or decoding method and apparatus, and more particularly, to a scalable audio encoding and/or decoding method and apparatus by using a wide-band excited signal and a frequency magnitude and phase of a residual signal in which a frequency envelope of the wide-band excited signal is removed from the wide-band excited signal.

2. Description of the Related Art

With an increased amount of audio communication applications in various fields, and an increase of network transmission speeds, there is an emerging demand for high fidelity audio communication. Accordingly, wide-band audio signals in a range of 0.3 kHz to 7 kHz which show excellent capability in terms of naturalness and clarity in comparison with known audio communication bands ranging from 0.3 kHz to 3.4 kHz are required to be transmitted.

In a network, a packet switching network in which data is transmitted in units of packets may cause a channel bottleneck, which may lead to packet loss and poor audio quality. To solve this problem, although a technique for hiding packet damage is used, this is not a fundamental solution. Thus, a technique for encoding/decoding a wide-band audio signal has been proposed to effectively compress the wide-band audio signal, and to solve the channel bottleneck.

Currently proposed methods of encoding/decoding wide-band audio signals include a first method in which audio signals in the range of 0.3 kHz to 7 kHz are simultaneously compressed and are then restored, a second method in which audio signals are scalably compressed by being divided into signals in the range of 0.3 kHz to 4 kHz and signals in a range of 4 kHz to 7 kHz, and are then restored, and a third method in which audio signals in a range of 0.3 to 3.4 kHz are compressed and restored, and thereafter the audio signals are over-sampled into a wide-band to obtain an original wide-band audio signal and a wide-band excited signal.

The second and third methods use a bandwidth scalability function for enabling optimum communication under a given condition by controlling a layer or a data size to be transmitted to a decoder through a network according to a data bottleneck condition.

In the second method, a high-band audio signal in the range of 4 kHz to 7 kHz is encoded using a modulated lapped transform (MLT) method. FIG. 1 is a block diagram illustrating a conventional apparatus for encoding a high-band audio signal using the MLT method.

Referring to FIG. 1, in the high-band audio signal encoding apparatus, when the high-band audio signal is input, the high-band audio signal input to an MLT unit 101 is processed using the MLT method, thereby extracting an MLT coefficient. A magnitude of the extracted MLT coefficient is output to a 2 dimension-discrete cosine transform (2D-DCT) unit (2D-DCT module) 102. A sign of the extracted MLT coefficient is output to a sign quantizer 103.

The 2D-DCT unit 102 extracts a 2D-DCT coefficient from the magnitude of the MLT coefficient, and outputs the extracted 2D-DCT coefficient to a DCT coefficient quantizer 104. The DCT coefficient quantizer 104 arranges 2D-DCT coefficients having a 2-dimensional structure according to a statistical size in descending order, quantizes arranged vectors corresponding to the arranged 2D-DCT coefficients, and outputs a codebook index. The sign quantizer 103 quantizes a sign of the extracted MLT coefficient and the quantized sign. The output codebook index and the quantized sign are provided to an apparatus (not shown) for decoding a high-band audio signal.

However, if the high-band audio signal is encoded using the MLT method, the audio signal cannot be easily restored with high fidelity when the audio signal is transmitted at a low bit-rate. Further, the lower a bit-rate, the poorer an audio restoring capability.

To solve this problem, as illustrated in FIG. 2, a conventional apparatus for encoding a high-band audio signal using a harmonic coder has been proposed.

Referring to FIG. 2, when the high-band audio signal is input, a harmonic peak detector 201 detects a harmonic peak of the high-band audio signal, and outputs an amplitude and phase of the high-band audio signal based on the detected harmonic peak.

A magnitude quantizer 202 quantizes an amplitude of the input high-band audio signal and outputs the quantized amplitude. A phase quantizer 203 quantizes a phase of the input high-band audio signal and outputs the quantized phase. The quantized amplitude and phase are provided to an apparatus (not shown) for decoding a high-band audio signal.

However, the apparatus of FIG. 2 using the harmonic coder has a limit in scalability of the input high-band audio signal even if high fidelity can be achieved with a low bit-rate and a low complexity.

As described above, in the third method of encoding a wide-band audio excited signal, audio signals in the band-range of 0.3 to 3.4 kHz are compressed and restored, and thereafter the audio signals are over-sampled into a wide-band to obtain an original wide-band audio signal and a wide-band excited signal. In this method, a wide-band excited signal in the range of 0.05 kHz to 7 kHz is encoded using a modified discrete cosine transform (MDCT) function.

FIG. 3 is a block diagram illustrating a conventional apparatus for encoding a wide-band excited signal using the MDCT method.

Referring to FIG. 3, when a wide-band audio signal is input, the apparatus for encoding a wide-band excited signal obtains a signal down-sampled into a low-band by a down sampling unit 301. This signal is encoded by a low-band encoder 302. The encoded audio signal is restored by an up-sampling unit 303 as a wide-band signal. A subtractor 304 subtracts the restored wide-band signal from an original signal (the wide-band audio signal), so as to generate a wide-band excited signal. The generated wide-band excited signal is input to an MDCT unit 305. The MDCT unit 305 extracts an MDCT coefficient of the input wide-band excited signal. The extracted MDCT coefficient is divided by a band division unit 306 for each band. The divided MDCT coefficient is normalized by a normalization unit 307. The normalized MDCT coefficient is quantized by a quantizer 308, so as to output the quantized coefficients as a codebook index. The output codebook index is provided to an apparatus (not shown) for decoding a high-band audio signal.

In the method of encoding the wide-band excited signal using the MDCT method, scalability can be supported unlike in the case of using the harmonic coder. However, since the MDCT coefficient of the input wide-band excited signal is divided for each band for encoding, and the encoding result is provided to the decoding apparatus (not shown), if the audio signal is transmitted at a low bit-rate, only a low frequency signal in a high-band can be restored, and a high frequency signal in the high-band cannot be restored. Therefore, when the audio signal is transmitted at a low bit-rate, it is difficult to restore the audio signal with high fidelity.

### SUMMARY OF THE INVENTION

The present general inventive concept provides a method and apparatus to scalably encode and/or decode an input signal, so as to restore the input signal with high fidelity even at a low bit-rate and to support a fine granularity scalable (FGS) function by scalably encoding a wideband audio signal using frequency information of a wideband excited signal, by encoding the wideband audio signal so as to restore a basic signal over an entire high-band of the wideband audio signal, and a computer-readable medium having embodied thereon a computer program to execute the method.

Additional aspects and advantages of the present general inventive concept will be set forth in part in the description which follows and, in part, will be obvious from the description, or may be learned by practice of the general inventive concept.

The foregoing and/or other aspects of the present general inventive concept may be achieved by providing a hierarchical encoding method including encoding a specific band signal included an input signal, encoding a frequency envelope of an excited signal in which the encoded specific band signal is removed from the input signal, encoding a residual signal in which the encoded frequency envelope is removed from the excited signal, and forming a bit-stream by scalably packing the encoded specific band signal, frequency envelop, and residual signal, wherein the specific band signal has a band defined not higher than a specific frequency of the input signal.

The encoding of the residual signal may comprise encoding frequency information of the residual signal. In this case, the frequency information on the residual signal may comprise at least one of a gain, a frequency magnitude, and a frequency phase of the residual signal.

The frequency information of the residual signal may comprise information on the frequency phase of the residual signal, and the encoding of the residual signal may comprise detecting a harmonic position of the input signal, encoding a frequency phase at the detected harmonic position, and encoding other frequency phases excluding the encoded frequency phase. In this case, the encoding of the other frequency phases may comprise analyzing a magnitude of a frequency envelope of the excited signal, and encoding the other frequency phases so that information on a magnitude of a frequency having a large analyzed magnitude is located in an upper bit in the bit-stream.

The encoding of the frequency information of the frequency magnitude of the residual signal may comprise, analyzing a magnitude of a frequency envelope of the excited signal, and encoding the frequency magnitude so that information on a phase of a frequency having a large analyzed magnitude is located in an upper bit in the bit-stream.

The forming of the bit stream may comprise packing a result obtained by encoding the specific band signal included in the input signal into a narrow-band layer, a result obtained by encoding the frequency envelope of the excited signal and a result obtained by encoding basic frequency information of the residual signal into a wide-band first layer, and frequency information other than the basic frequency information of the residual signal into a wide-band expansion layer.

The foregoing and/or other aspects of the present general inventive concept may also be achieved by providing a hierarchical encoding method comprising encoding a specific band signal included in an input signal, encoding a frequency envelope of an excited signal obtained by down-sampling a signal in which the encoded specific band signal is removed from the input signal, encoding a residual signal in which the encoded frequency envelope of the encoded exited signal is removed from the excited signal, encoding a gain of a high frequency signal obtained by removing the excited signal from the signal in which the encoded specific band signal is removed from the input signal, and forming a bit-stream by scalably packing the encoded specific band signal, frequency envelop, residual signal, and gain of the high frequency signal.

The foregoing and/or other aspects of the present general inventive concept may also be achieved by providing a hierarchical encoding apparatus comprising a low-band encoder to encode a specific band signal included in an input signal, a linear prediction analyzer to encode a frequency envelope of an excited signal in which the encoded specific band signal is removed from the input signal, a frequency encoder to encode a residual signal in which the encoded frequency envelope is removed from the excited signal, and a multiplexer to form a bit-stream by scalably packing the encoding results of the low-band encoder, the linear prediction analyzer, and the frequency encoder.

The foregoing and/or other aspects of the present general inventive concept may also be achieved by providing a hierarchical decoding method comprising dividing a received bit-stream by depacking the bit stream for each of a plurality of layers, restoring a specific band signal included in an input signal, a frequency envelope of an excited signal in which the encoded specific band signal is removed from the input signal, and a residual signal in which the encoded frequency envelope is removed from the excited signal, by decoding each of the divided layers, restoring the excited signal by using the frequency envelope of the restored excited signal and the restored residual signal, and restoring the input signal by synthesizing the restored excited signal and the specific band signal of the input signal, wherein the specific band may be defined as a band no more than a specific frequency of the input signal.

The dividing of the received bit stream may comprise depacking the received bit-stream for each of the layers into a narrow-band layer comprising a result obtained by encoding the specific band signal included in the input signal, a wide-band first layer comprising a result obtained by encoding the frequency envelope of the excited signal and a result obtained by encoding basic frequency information of the residual signal, and a wide-band expansion layer comprising frequency information other than the basic frequency information of the residual signal.

The restoring of the specific band signal may comprise restoring frequency information of the residual signal by decoding each of the divided layers, and restoring the residual signal by using the restored frequency information, wherein the frequency information of the residual signal may comprise a gain, a frequency magnitude, and/or a frequency phase of the residual signal.

The restoring of the frequency phase of the residual signal may comprise restoring information on a frequency phase of the input signal at a harmonic position from the frequency phase of the residual signal, or may further comprise restoring frequency phases other than the frequency phase of the input signal at the harmonic position.

The restoring of the other frequency phases may comprise analyzing a magnitude of the restored frequency envelope, and restoring the other frequency phases according to the analyzed magnitude in descending order.

The restoring of the frequency magnitude of the residual signal may comprise analyzing a magnitude of the restored frequency envelope, and restoring the frequency magnitude according to the analyzed magnitude in descending order.

The foregoing and/or other aspects of the present general inventive concept may also be achieved by providing a hierarchical decoding method comprising dividing a received bit-stream by depacking the bit stream for each of a plurality of layers, restoring a specific band signal included in an input signal, a frequency envelope of an excited signal which is obtained by down-sampling a signal in which the encoded specific band signal is removed from the input signal, a residual signal in which the encoded frequency envelope of the excited signal is removed from the excited signal, and a gain of a high frequency signal which is obtained by removing the down-sampled excited signal from the signal in which the encoded specific band signal is removed from the input signal, by decoding each of the divided layers, restoring the excited signal by using the frequency envelope of the restored excited signal and the restored residual signal, restoring the high frequency signal by using the gain of the high frequency signal, and restoring the input signal by synthesizing a signal obtained by over-sampling the restored excited signal, and the restored high frequency signal, and the specific band signal included in the restored input signal.

The foregoing and/or other aspects of the present general inventive concept may also be achieved by providing a hierarchical decoding apparatus comprising a demultiplexer to divide a received bit-stream by depacking the bit stream for each of a plurality of layers, a decoder to restore a specific band signal included in an input signal by decoding the divided layers, a frequency decoder to restore a specific band signal included in an input signal, a frequency envelope of an excited signal in which the encoded specific band signal is removed from the input signal, and a residual signal in which the encoded frequency envelope is removed from the excited signal, by decoding each of the divided layers, a linear prediction synthesizer to restore the frequency envelope of the excited signal by decoding the divided layers and synthesizing the excited signal by using the restored frequency envelope and the restored residual signal, and a synthesizer to restore the input signal by using the specific band signal of the restored input signal and the restored excited signal.

The foregoing and/or other aspects of the present general inventive concept may also be achieved by providing a computer-readable medium having embodied thereon a computer program for executing the hierarchical encoding/decoding method.

The foregoing and/or other aspects of the present general inventive concept may also be achieved by providing a signal processing system to encode and/or decode an audio signal, comprising an encoding apparatus and a decoding apparatus, the encoding apparatus including a low-band encoder to encode a specific band signal included in a first input signal, a linear prediction analyzer to encode a frequency envelope of an excited signal in which the encoded specific band signal is removed from the input signal, a frequency encoder to encode a residual signal in which the encoded frequency envelope is removed from the excited signal, and a bit packing unit to form a bit-stream by scalably packing the encoding results of the low-band encoder, the linear prediction analyzer, and the frequency encoder, and the decoding apparatus including a bit depacking unit to divide the bit-stream by depacking the bit stream for each of a plurality of layers, a decoder to restore the specific band signal included in a second input signal by decoding the divided layers, a frequency decoder to restore the frequency envelope of the excited signal in which the encoded specific band signal is removed from the input signal, and the residual signal in which the encoded frequency envelope is removed from the excited signal, by decoding each of the divided layers, a linear prediction synthesizer to restore the frequency envelope of the excited signal by decoding the divided layers, and to synthesize the excited signal by using the restored frequency envelope and the restored residual signal, and a synthesizer to restore the input signal by using the specific band signal of the restored input signal and the restored excited signal.

The foregoing and/or other aspects of the present general inventive concept may also be achieved by providing a signal processing system to process an audio signal, including an encoding apparatus to receive an audio signal, and to generate from the audio signal a bit stream having a narrow-band layer, a wide-band first layer, and an expansion layer in order; and a decoding apparatus to decode the bit stream, restore a low band signal, a basic audio signal, and an expanded audio signal of the audio signal according to the narrow-band layer, the wide-band first layer, and the expansion layer, respectively, and to produce an output audio signal according to a combination of the low-band signal, the basic audio signal, and the expanded audio signal.

The foregoing and/or other aspects of the present general inventive concept may also be achieved by providing a signal processing system to encode an audio signal, including an encoding apparatus to receive an audio signal, and to generate from the audio signal a bit stream having a narrow-band layer, a wide-band first layer, and an expansion layer in order.

The foregoing and/or other aspects of the present general inventive concept may also be achieved by providing a signal processing system to process an audio signal, including a decoding apparatus to decode a bit stream having a narrow-band layer, a wide-band first layer, and an expansion layer in order, to restore a low band signal, a basic audio signal, and an expanded audio signal of the audio signal according to the narrow-band layer, the wide-band first layer, and the expansion layer, respectively, and to produce an output audio signal according to a combination of the low-band signal, the basic audio signal, and the expanded audio signal.

The foregoing and/or other aspects of the present general inventive concept may also be achieved by providing a signal processing system to process an audio signal, including a decoding apparatus to decode a bit stream having a narrow-band layer and a wide-band first layer having information on an LPC of an excited signal of a high-band signal of the audio signal, a gain index of a residual signal of the excited signal, and a phase index of the high-band signal of the residual signal at a harmonic location thereof, in order, to restore a low band signal and a basic audio signal of the audio signal according to the narrow-band layer and the wide-band first layer, respectively, and to produce an output audio signal according to a combination of the low-band signal and the basic audio signal.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a block diagram illustrating a conventional apparatus for encoding a high-band audio signal using a modulated lapped transform (MLT) method;

FIG. 2 is a block diagram illustrating a conventional apparatus for encoding a high-band audio signal using a harmonic coder;

FIG. 3 is a block diagram illustrating a conventional apparatus for encoding a wide-band excited signal using a modified discrete cosine transform (MDCT) method;

FIG. 4 is a block diagram illustrating a hierarchical encoding and/or decoding apparatus according to an embodiment of the present general inventive concept;

FIG. 5A is a block diagram illustrating the hierarchical encoding apparatus of FIG. 4;

FIG. 5B is a block diagram illustrating the hierarchical decoding apparatus of FIG. 4;

FIG. 6A is a block diagram illustrating a frequency quantizer of the hierarchical encoding apparatus of FIG. 5A;

FIG. 6B is a block diagram illustrating a frequency magnitude quantizer of the frequency quantizer of FIG. 6A;

FIGS. 7A and 7B are flowcharts illustrating a hierarchical encoding method according to an embodiment of the present general inventive concept;

FIGS. 7C and 7D are flowcharts illustrating a hierarchical decoding method according to an embodiment of the present general inventive concept;

FIG. 8 is a flowchart illustrating an operation of quantizing a frequency magnitude and phase of a residual signal of the method of FIGS. 7A and 7B; and

FIG. 9 is a view illustrating a bit-stream of an input signal encoded according to an embodiment of the present general inventive concept.

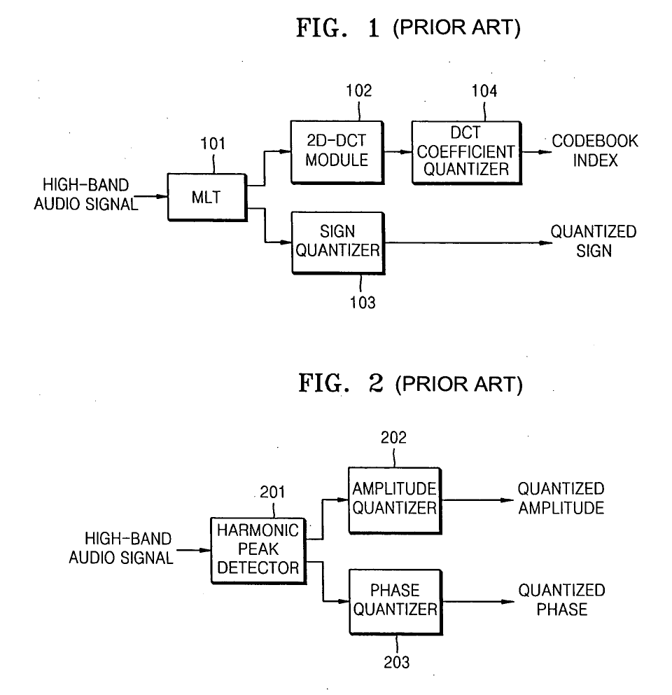

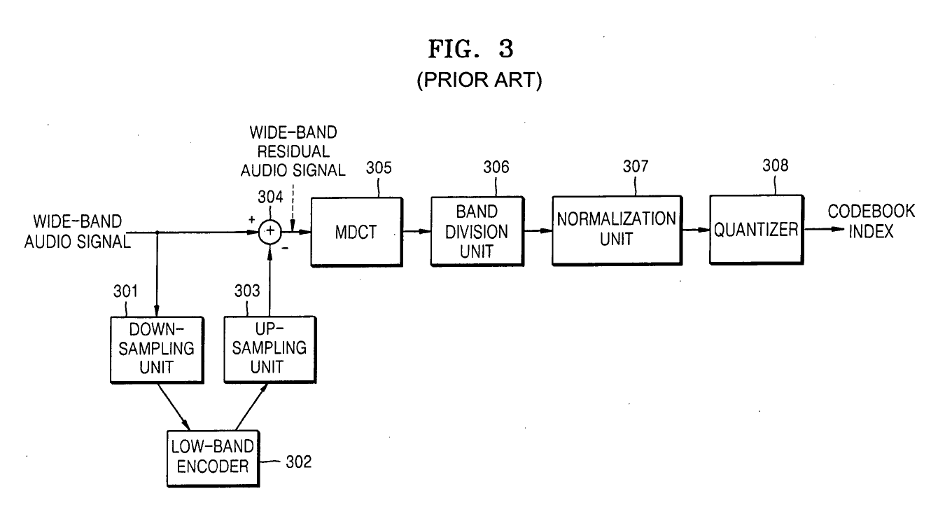

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

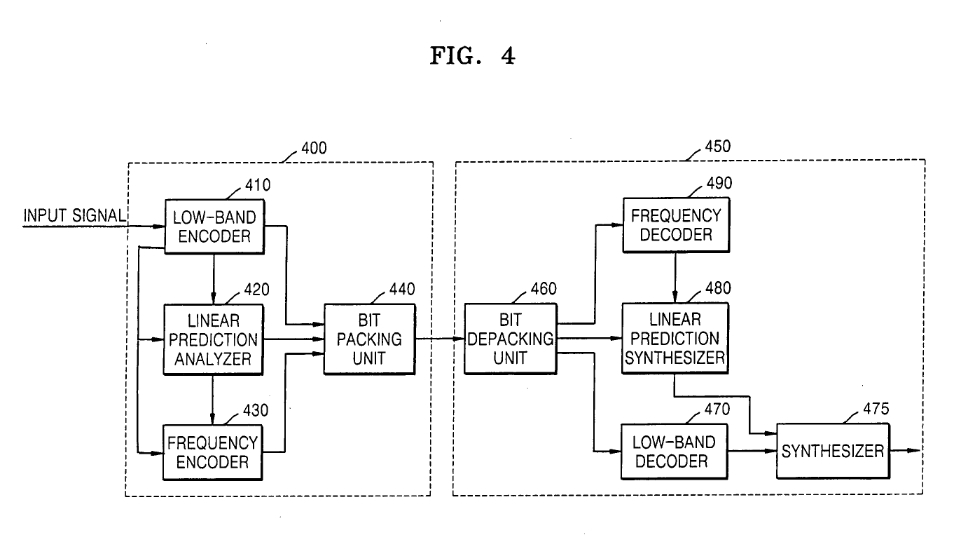

FIG. 4 is a block diagram illustrating a signal processing system having a hierarchical encoding apparatus 400 and a hierarchical decoding apparatus 450 according to an embodiment of the present general inventive concept. The signal processing system may be an audio signal processing system to process an audio signal, for example, to encode and decode the audio signal. The audio signal may be either a speech signal or a sound signal. The hierarchical encoding apparatus 400 includes a low-band encoder 410, a linear prediction analyzer 420, a frequency encoder 430, and a bit packing unit 440. The hierarchical decoding apparatus 450 includes a bit dividing unit (bit depacking unit) 460, a low-band decoder 470, a linear prediction synthesizer 480, a frequency decoder 490, and a synthesizer 475.

The encoding apparatus 400 encodes the audio signal input through an input terminal, and forms a bit-stream from the encoded audio signal. The formed bit-stream is transmitted to the decoding apparatus 450. The decoding apparatus 450 decodes the received bit-stream to restore the audio signal, and outputs the restored audio signal.

The audio signal is input through the input terminal for a predetermined period of time. Further, the input audio signal may be composed of a plurality of discrete data signals that are pulse code modulated (PCM). The audio signal input for the predetermined time may be composed of a plurality of frames each having a number of discrete data signals. A frame is defined as a unit of process for encoding and/or decoding.

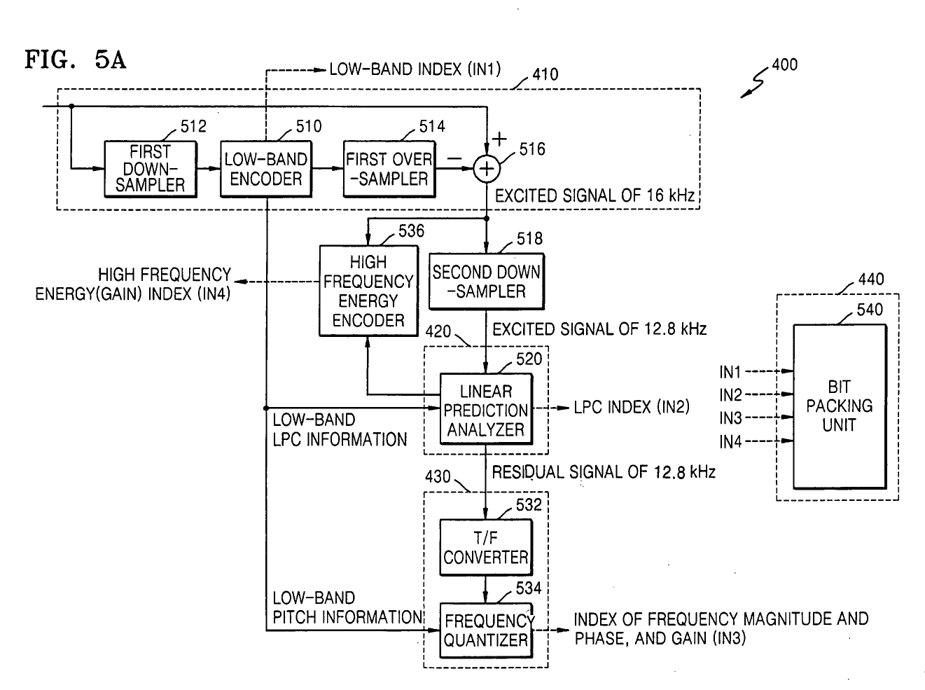

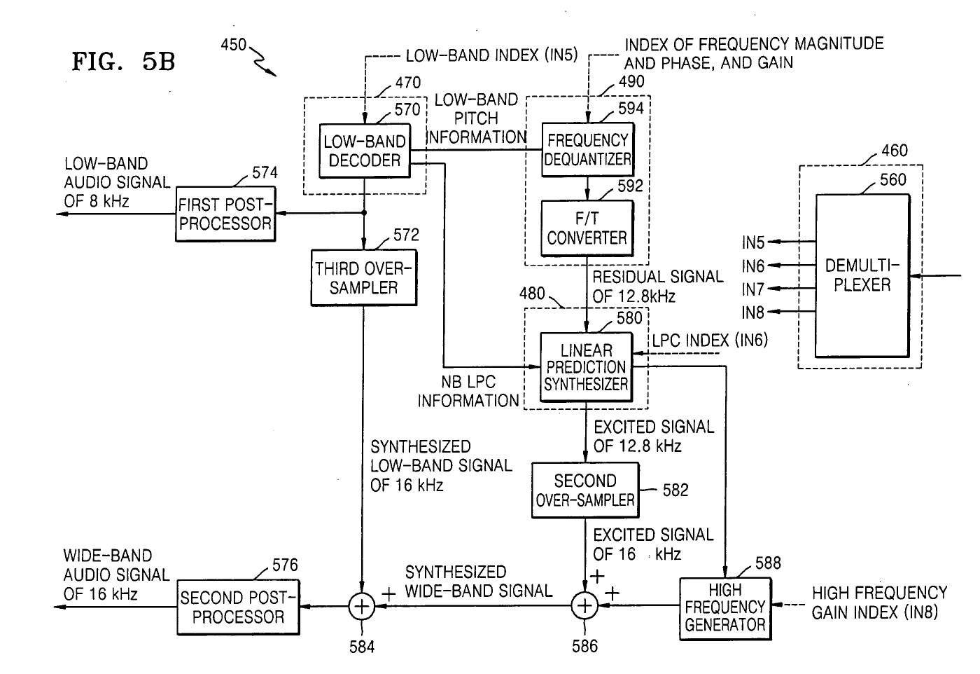

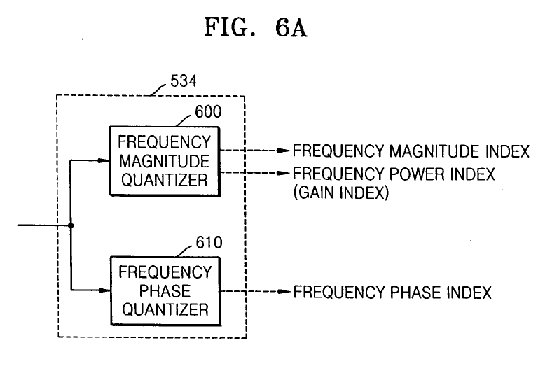

FIG. 5A is a block diagram illustrating the encoding apparatus 400 of the signal processing system of FIG. 4. Now, a structure and operation of the encoding apparatus 400 according to an embodiment of the present general inventive concept will be described in detail with reference to FIGS. 4 and 5A.

Referring to FIGS. 4 and 5A, the encoding apparatus 400 includes a low-band encoder 510, a first down-sampler 512, a first over-sampler 514, a first subtractor 516, a second down-sampler 518, a linear prediction analyzer 520, a time/frequency converter 532, a frequency quantizer 534, a high frequency energy encoder 536, and a bit packing unit 540. It will be assumed that an audio signal input to the encoding apparatus 400 is a wide-band audio signal having a bandwidth of 16 kHz. The low-band encoder 510, the first down-sampler 512, the first over-sampler 514, and the first subtractor 516 of FIG. 5A may constitute the low-band encoder 410 of FIG. 4, the bit packing unit 540 and terminals to receive encoded signals, such as a first index signal (IN1), a second index signal (IN2), a third index signal (IN3), and a fourth index signal (IN4) of FIG. 5A may constitute the bit packing unit 440 of FIG. 4, and the time/frequency converter 532 and the frequency quantizer 534 of FIG. 5A may constitute the frequency encoder 430 of FIG. 4.

First, the first down-sampler 512 receives an original 16 kHz signal as the input audio signal to be down-sampled to obtain an 8 kHz signal, and inputs the 8 kHz down-sampled signal to the low-band encoder 510.

The low-band encoder 510 encodes the 8 kHz down-sampled signal, that is, a low-band audio signal, and extracts a low-band index. In other words, the low-band encoder 510 encodes the low-band audio signal, and searches for an encoding result from a codebook, so as to extract an index value of the searched result as the low-band index. The low-band encoder 510 may encode the low-band signal according to G. 729. Here, G. 729 is an audio data compression algorithm for voice. However, this is only an exemplary embodiment, and various encoding methods can be used in the low-band encoder 510. The extracted low-band index is transmitted to the bit packing unit 540 as the first index signal (IN1). Further, the low-band encoder 510 synthesizes the original signal down-sampled to 8 kHz, that is, the low-band signal, by using the extracted low-band index.

The first over-sampler 514 over-samples the synthesized low-band audio signal, so as to be converted to a 16 kHz signal. In this case, since the converted 16 kHz signal is over-sampled only using the synthesized low-band audio signal, a high-band frequency component is not included.

In order to synthesize a high-band signal and/or a signal that has not been synthesized by the low-band encoder 510, the first subtractor 516 removes the synthesized signal of the 16 kHz signal of the first over-sampler 514 from the original audio signal of 16 kHz, and extracts a 16 kHz wide-band excited signal.

The second down-sampler 518 down-samples the extracted 16 kHz wide-band excited signal to a 12.8 kHz signal, and inputs the 12.8 kHz signal to the linear prediction analyzer 520 as a 12.8 kHz wide-band excited signal.

In order to analyze a frequency envelope of the 12.8 KHz wide-band excited signal, the linear prediction analyzer 520 generates a linear prediction coefficient (LPC) by using an auto-correlation method and a Levinson Durbin algorithm, and extracts an index of the generated LPC. Although the above methods used by the linear prediction analyzer 520 generate the LPC according to the present embodiment, a variety of methods can be used to generate the LPC of the wide-band excited signal.

A low-band component of the LPC generated by the linear prediction analyzer 520 may be replaced with the low-band component of an LPC (low-band LPC information) generated by the low-band encoder 510. When the low-band component of the LPC ranges to 8 kHz, the linear prediction analyzer 520 can quantize only a high-frequency component of the LPC that represents information on a frequency envelope of the high-frequency component ranging from 8 kHz to 12.8 kHz. Thus, the decoding apparatus 450 can restore a frequency envelope of the low-band component of the wide-band excited signal using the LPC encoded by the low-band encoder 510 and can also restore the frequency envelop of the high-frequency component using of the LPC of the linear prediction analyzer 520. The linear prediction analyzer 520 quantizes the generated LPC, extracts an index of the quantized LPC, and transmits the extracted LPC index to the bit packing unit 540 as the second index signal (IN2).

The linear prediction analyzer 520 performs a linear prediction analysis on the 12.8 kHz wide-band excited signal by using the extracted LPC. When the linear prediction analysis is preformed in a frequency domain, a linear prediction residual signal having a flat frequency domain characteristic is generated by removing the frequency envelope of the wide-band excited signal.

Up to this point, an audio signal input for each of a plurality of frames can be processed. As described above, a frame is a process unit for the input audio signal, and one frame can be divided into a plurality of sub-frames. Then an encoding process can be performed on each of the sub-frames.

The time/frequency converter 532 receives the linear prediction residual signal (residual signal of 12.8 kHz) generated by the linear prediction analyzer 520, and converts the linear prediction residual signal from the time domain to the frequency domain. The time/frequency conversion process can be performed using various methods. In the present embodiment, the time/frequency conversion process is performed using a fast Fourier transform (FFT). However, this is an only exemplary embodiment, and other methods that can be clearly understood by those skilled in the art may be used.

When the time/frequency converter 532 uses the FFT, N time domain values of the linear prediction residual signal are output as 2N frequency components in a form of a complex number. The 2N frequency components have a symmetric shape except for 0th and Nth components. Thus, information on a frequency component of the linear prediction residual signal can be represented by using N symmetric complex numbers among a total of 2N complex numbers when the N^{th} data that is a Nyquist frequency component is considered as 0. A frequency component value of the linear prediction residual signal that is output from the time/frequency converter 532 in the form of the complex number may be divided into frequency magnitude and phase information for quantization. Information on frequency magnitude and phase may be represented by using various quantization methods such as vector quantization (VQ), scalar quantization (SQ), split VQ (SVQ), and multi-stage split VQ (MSVQ) according to restrictions such as a transmission rate, a memory capacity, and complexity.

The frequency quantizer 534 receives the information on the frequency magnitude and phase of the linear prediction residual signal, and quantizes the magnitude and phase to extract an index of the quantized frequency magnitude and phase. The extracted index is transmitted to the bit packing unit 540 as the third index signal (IN3). Further, the frequency quantizer 534 calculates and quantizes a gain (power) of the linear prediction residual signal by using the frequency magnitude of the input linear prediction residual signal, extracts a gain index (or power index) of the quantized gain (power) of the linear prediction residual signal, and transmits the extracted gain index to the bit packing unit 540 together with the index of the quantized frequency magnitude and phase as the third index signal (IN3). The frequency quantizer 534 can also generate an index of magnitude and phase of the low-band signal according to low-band pitch information generated from the low-band encoder 410 as the third index signal (IN3).

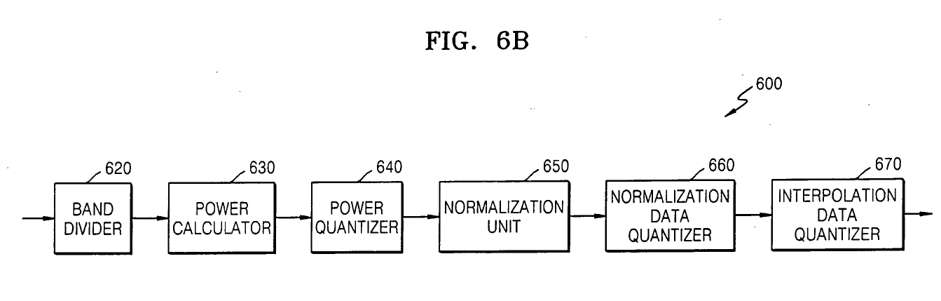

FIG. 6A is a block diagram illustrating the frequency quantizer 534 of FIG. 5. The frequency quantizer 534 includes a frequency magnitude quantizer 600 and a frequency phase quantizer 610. FIG. 6B is a block diagram illustrating the frequency magnitude quantizer 600 of FIG. 6A. Now, a method of quantizing a frequency magnitude and phase of the linear prediction residual signal and a method of quantizing a frequency power of the linear prediction residual signal will be described with reference to FIGS. 4, 5, 6A, and 6B. The frequency magnitude quantizer 600 includes a band divider 620, a power calculator 630, a power quantizer 640, a normalization unit 650, a normalization data quantizer 660, and an interpolation data quantizer 670.

Now, an operation of the frequency magnitude quantizer 600 will be described. As described above, a process of analyzing the linear prediction residual signal can be processed for each of the sub-frames constituting one frame.

First, the band divider 620 receives the frequency magnitude obtained by the time/frequency converter 532 for each sub-frame, and divides the received frequency magnitude into K sub-bands in the frequency domain. The power calculator 630 calculates a frequency power of the frequency magnitude for each sub-band. The frequency power can be calculated using Formula 1.

$$p = \frac{1}{e - s + 1} {\sum }_{n = s}^{e} {m}_{n}^{2} \qquad [ Formula 1 ]$$

Here, s (start) and e (end) respectively denote a first frequency index and a last frequency index for each sub-band, and mₙ denotes an n^{th} frequency magnitude in a sub-frame. Thus, if a frequency band is divided into K sub-bands by the band divider 620, K frequency power information is generated, and the generated frequency power information is calculated by the power calculator 630 and quantized by the power quantizer 640. Since the frequency power information of each sub-band has strong correlation with one another, it is grouped into K vectors, and then vector-quantized. The quantized power information corresponds to information on a gain value of the linear prediction residual signal. Thus, the quantized frequency power information is provided to the decoding apparatus 450 as the power index (gain index) of the third index signal (IN3). When a layered structure is supported in decoding, an additional gain is required for each layer in order to correctly restore energy. Since a last magnitude is always defined according to this method, energy can be restored for each layer without the additional gain.

The normalization unit 650 divides the frequency magnitude of each sub-band with a frequency power value (frequency power information) of each sub-band quantized by the power quantizer 640, and normalizes the result (divided frequency magnitude). The normalization data quantizer 660 quantizes the normalized frequency magnitude.

The frequency magnitude quantizer 600 may quantize all frequency magnitude normalized by the normalization unit 650, and extract an index of quantized frequency magnitudes to be output to the bit packing unit (or multiplexer) 440 as the magnitude index of the third index signal (IN3). However, according to the present embodiment, the frequency magnitude quantizer 600 may quantize only a part of the frequency magnitudes normalized by the normalization unit 650, and the non-quantized frequency magnitudes may be quantized by interpolating the quantized frequency magnitudes in the interpolation data quantizer 670. Now, an operation of quantizing the frequency magnitudes using an interpolating method will be described.

The normalization data quantizer 660 quantizes only a part of the normalized frequency magnitudes. For example, either all odd frequency magnitudes or all even frequency magnitudes may be quantized. Thereafter, the interpolation data quantizer 670 interpolates the non-quantized even or odd frequency magnitudes by the normalization data quantizer 660.

The aforementioned process may be processed for each sub-frame as described above. In this case, the frequency magnitude quantizer 600 may quantize only a frequency magnitude of a part of the sub-frames, and a frequency magnitude of the non-quantized sub-frames may be quantized by interpolating the frequency magnitude of the quantized sub-frames. For example, if one frame is composed of two sub-frames, only a frequency magnitude of a first sub-fame of each frame is quantized, and thereafter a frequency magnitude of a non-quantized second sub-frame is quantized by interpolating the quantized value of the first sub-frame.

The frequency magnitude quantizer 600 extracts the index of the quantized frequency magnitude, and outputs the index to the bit packing unit 540 as the magnitude index. Further, the frequency magnitude quantizer 600 extracts the gain index (power index) of the quantized frequency power information extracted in the frequency quantizer 640 using a frequency magnitude quantizing process, and outputs the index to the bit packing unit 540 as the gain index (power index). The frequency power information corresponds to gain information of the linear prediction residual signal. The bit packing unit 540 performs bit-packing on the quantized frequency magnitude and the index of the gain value, so as to be transmitted to the decoding apparatus 450 in the form of a bit-stream. The decoding apparatus 450 decodes the frequency magnitude and the gain value from the received bit-stream, and obtains a scaled frequency magnitude by multiplying a frequency power to the normalized frequency magnitude by using the decoding result (decoded frequency magnitude and gain value).

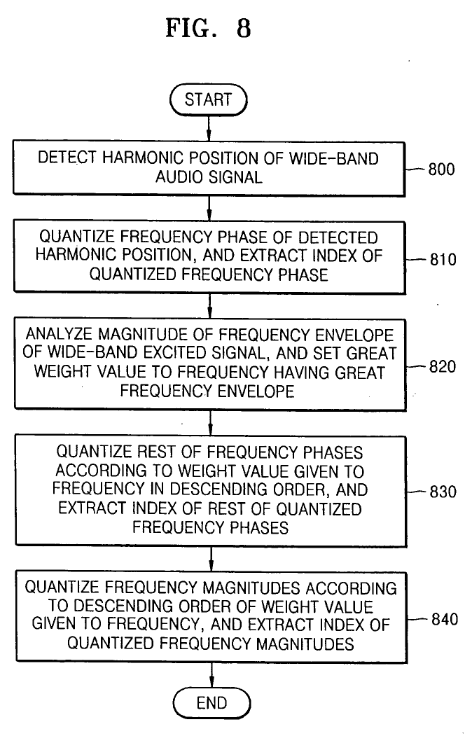

FIG. 8 is a flowchart illustrating a method of quantizing a frequency magnitude and phase of the linear prediction residual signal in the frequency quantizer 534 of FIG. 6A according to an embodiment of the present general inventive concept. Now, a method of quantizing a frequency magnitude and phase of a linear prediction residual signal according to an embodiment of the present invention will be described with reference to FIGS. 4, 5, 6A, 6B, and 8.

The method of quantizing the frequency phase includes a process of quantizing the frequency phase at a harmonic position, and a process of quantizing non-quantized frequency phases.

In operation 800, the frequency quantizer 534 detects a harmonic position of the wide-band audio signal.

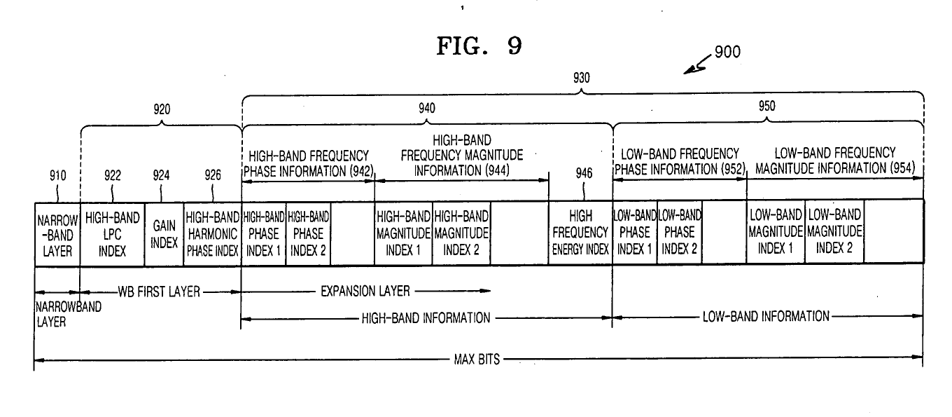

In operation 810, the frequency quantizer 534 quantizes a frequency phase at the detected harmonic position, and extracts an index of the quantized frequency phase as the frequency phase index. In order to provide the wide-band audio signal in a wide-band layer, a harmonic component of an audio signal needs to be transmitted. Thus, in the present embodiment, a phase associated with the harmonic position of the wide-band audio signal in the frequency domain is firstly extracted, and then the other frequency phases may be quantized according to the extracted phase. The index related to the frequency phase at the harmonic position extracted in operation 810 is transmitted to the bit packing unit 540 as a harmonic frequency phase index of the third index signal (IN3), i.e., a high-band harmonic phase index 926 (see FIG. 9). The bit packing unit 540 transmits the harmonic frequency phase index to the decoding apparatus 450 by including an index in a wide-band first layer that can restore all high-band basic audio signals.

In this case, the harmonic position of the audio signal can be easily obtained by using information on a pitch of a low-band audio signal extracted by the low-band encoder 510, that is, low-band pitch information. When a frequency band of the low-band audio signal is 8 kHz, and a frequency band of the wide-band audio signal is 16 kHz, if pitch information (the low-band pitch information) extracted by the low-band encoder 510 is τ, then a position Iᵢ of an i^{th} harmonic position can be obtained using Formula 2.

$${l}_{i} = ⌊ \frac{N}{0.8 ⨯ τ} ⨯ i - 0.5 ⌋ \qquad [ Formula 2 ]$$

Here, N is the number of frequency components.

In the encoding apparatus 400 according to the present embodiment, the frequency phase information at the harmonic position is located upper bit than the rest of the frequency phase information in the bit stream. Thus, a basic audio quality of a high-band signal can be compensated for with a minimum number of bits by using the frequency phase information at the harmonic position.

In general, a signal having a long pitch may have a large number of harmonics, whereas a signal having a short pitch may have a less number of harmonics. Therefore, considering a bit assigned for the wide-band first layer, the frequency phase information at the harmonic position to be quantized may be restricted. In this case, the wide-band first layer may be formed by quantizing only a part of the frequency phase information at the harmonic position. For this reason, when only a part of information on the frequency phase at the harmonic position is included in the wide-band first layer, and is transmitted to the decoding apparatus 450, the decoding apparatus 450 can fill (obtain) phase information on a non-quantized harmonic position by using a random phase corresponding to the phase information of the harmonic position. The decoding apparatus 450 may restore a basic audio signal over the entire high-band by using the phase information at the harmonic position included in the wide-band first layer and linear prediction information extracted by the linear prediction analyzer 420.

If it is determined that there is a frequency phase at a harmonic position that is not included in the wide-band first layer, it may be transmitted to the decoding apparatus 450 by quantizing the frequency phase at the harmonic position not included in the wide-band first layer, and then by being included in the wide-band first layer.

In operations 820 to 840, other frequency phases not quantized in operation 810 are quantized, and an index of the quantized frequency phases are extracted. The rest of the frequency phases are sequentially quantized using a frequency envelope of a signal corresponding to the wide-band excited signal (i.e., excited signal of 12.8 kHz).

In operation 820, the frequency quantizer 534 sets a high weight value to a frequency having a high frequency envelope of the wide-band excited signal by using the LPC generated by the linear prediction analyzer 520.

In operation 830, the frequency quantizer 534 quantizes the other frequency phases according to the weight value in descending order given to the frequency having the high frequency envelop of the wide-band excited signal, and extracts an index of the other quantized frequency phases.

In operation 840, the frequency quantizer 534 quantizes frequency magnitudes according to the weight value given to the frequency having the high frequency envelop of the wide-band excited signal in descending order, and extracts an index of the quantized frequency magnitudes.

In operations 820 to 840, information on a frequency having a great frequency envelope of the wide-band first layer is placed at an upper bit of a bit-stream, and information an a frequency having a small frequency envelope is placed at the lower bit of the bit-stream. This is because the frequency phase at a location where the magnitude of a frequency envelope is great may be regarded as more important information in terms of improving audio quality when an audio signal is restored. In this case, a unit of quantization for the frequency phase may be determined such that a bit is assigned to fit a fine granularity scalable (FGS) unit to be provided in coding the audio signal.

Referring back to FIG. 5A, the frequency information on the 12.8 kHz wide-band excited signal output from the second down-sampler 518 is extracted using the aforementioned processes. However, since the 16 kHz wide-band excited signal is down-sampled to 12.8 kHz by the second down-sampler 518, the frequency information on the wide-band audio signal of 12.8 kHz or higher may be lost in the frequency domain.

In order to compensate for the lost frequency information, the high frequency energy encoder 536 calculates a difference between a high frequency energy of the 16 kHz wide-band excited signal and a pseudo high frequency energy generated by using the LPC for the 12.8 kHz wide-band excited signal extracted by the linear prediction analyzer 520, quantizes the result (i.e., the calculated difference), and extracts an index (high frequency energy information) of the quantized difference as the fourth index signal (IN4) (operation 730). The decoding apparatus 450 restores high energy information, that is, a gain index of a high frequency signal, by decoding the high frequency energy information index of the fourth index signal (IN4) from a received bit-stream, generates a pseudo high frequency through a random number generator by using the restored high frequency energy information and the restored LPC, thereby compensating for the wide-band audio signal of 12.8 kHz or higher.

After the 16 kHz wide-band excited signal is down-sampled to 12.8 kHz by the second down-sampler 518, the high frequency energy encoder 536 encodes the down-sampled 16 kHz wide-band excited signal. According to another embodiment of the present general inventive concept, the 16 kHz wide-band excited signal output from the subtractor 516 may be encoded by the linear prediction analyzer 520 and the frequency encoder 430 without including the second down-sampler 518 and the high frequency energy encoder 536, so that an audio signal can be restored over the entire high-band.

The bit packing unit 540 scalably packs each index extracted by the low-band encoder 510, the linear prediction analyzer 520, the frequency quantizer 534, and the high frequency energy encoder 536 for transmission, and forms a bit-stream. The bit-stream is formed in a layered manner such that a low-band index is included in a narrow-band layer, the LPC index, the gain index of the linear prediction residual signal, and a frequency index at a harmonic position are included in a wide-band first layer, and the other indexes, that is, an index of a frequency magnitude of the linear prediction residual signal, an index of the rest of frequency phases excluding a frequency phase at the harmonic position of the linear prediction residual signal and an index of a high frequency energy are included in a wide-band expansion layer. Thereafter, the bit-stream is transmitted to the decoding apparatus 450.

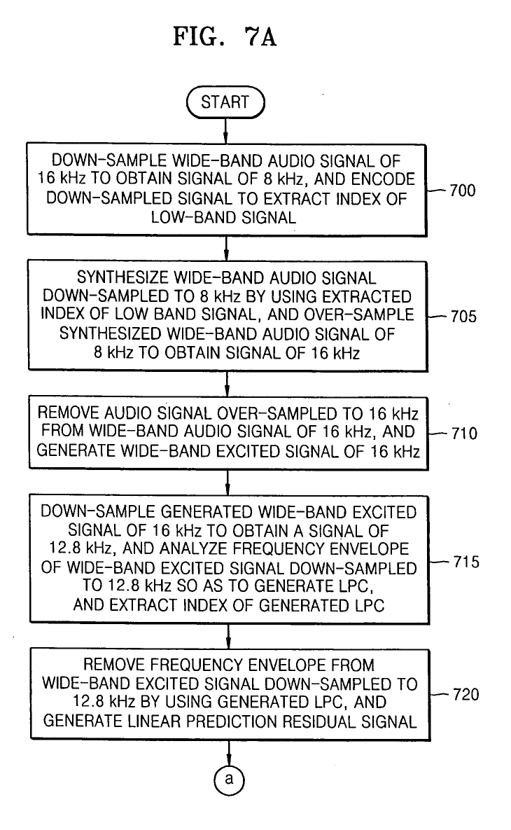

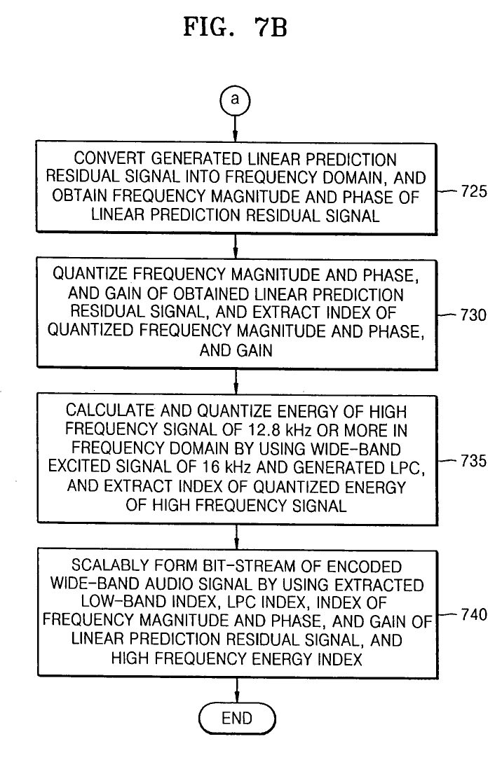

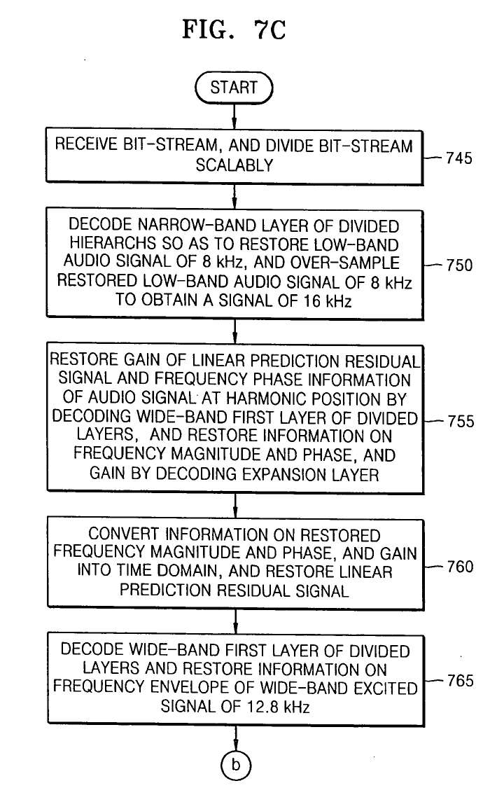

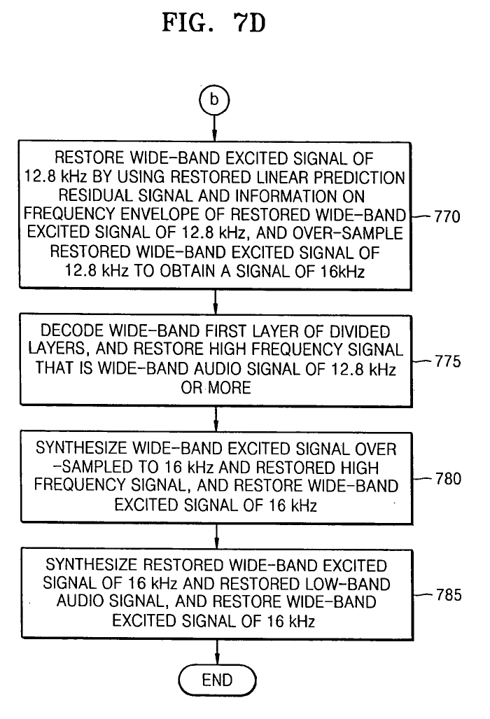

FIGS. 7A and 7B are flowcharts illustrating a hierarchical encoding method according to an embodiment of the present general inventive concept. Now, the hierarchical encoding method will be described with reference to FIGS. 4, 5A, 6A, 6B, 7A, and 7B.

In operation 700, the encoding apparatus 400 down-samples a 16 kHz wide-band audio signal to obtain an 8 kHz low-band signal, and encodes the down-sampled 8 kHz low band signal so as to extract an index of the low-band signal as the first index signal (IN1).

In operation 705, the encoding apparatus 400 synthesizes the 16 kHz wide-band audio signal down-sampled to 8 kHz by using the extracted index of the low band signal, and over-samples the synthesized 8 kHz wide-band audio signal to obtain a 16 kHz wide-band signal.

In operation 710, the encoding apparatus 400 removes the audio signal over-sampled to 16 kHz from the original 16 kHz wide-band audio signal, and generates a 16 kHz wide-band excited signal.

In operation 715, the encoding apparatus 400 down-samples the generated 16 kHz wide-band excited signal to obtain a 12.8 kHz signal, analyses a frequency envelope of the wide-band excited signal down-sampled to 12.8 kHz so as to generate an LPC, and extracts an index of the generated LPC as the second index signal (IN2).

In operation 720, the encoding apparatus 400 removes a frequency envelope from the wide-band excited signal down-sampled to 12.8 kHz by using the generated LPC, and generates a linear prediction residual signal.

In operation 725, the encoding apparatus 400 converts the generated linear prediction residual signal into the frequency domain, and obtains a frequency magnitude and phase of the linear prediction residual signal.

In operation 730, the encoding apparatus 400 quantizes the gain (power) and the frequency magnitude and phase index of the obtained linear prediction residual signal, and extracts each index of the quantized gain and the frequency magnitude and phase.

In operation 735, the encoding apparatus 400 calculates and quantizes energy of a high frequency signal of 12.8 kHz or higher in the frequency domain by using the 16 kHz wide-band excited signal and the generated LPC, and extracts an index of the quantized energy of the high frequency signal as the fourth index signal (IN4).

In operation 740, the encoding apparatus 400 forms a bit-stream of an encoded wide-band audio signal by scalably packing the low-band index (i.e., first index signal IN1) extracted in operation 700, the LPC index (i.e., second index signal IN2) extracted in operation 715, the frequency magnitude and phase, and the gain index of the linear prediction residual signal (i.e., third index signal IN3) extracted in operation 730, and the energy index of the high frequency signal (i.e., fourth index signal IN4) extracted in operation 735, that is, the gain index of the high frequency signal. Thereafter, the encoding apparatus 400 transmits the formed bit-stream having one or more of the first, second, third, and fourth index signals IN1, IN2, IN3, and IN4 to the decoding apparatus 450.

FIG. 9 illustrates a scalably encoded bit-stream 900 according to an embodiment of the present general inventive concept. The bit-stream 900 may include a narrow-band layer 910 to restore a low-band signal, a wide-band first layer 920 to restore a basic audio signal over an entire high-band, and an expansion layer 930 to scalably restore a wide-band audio signal including the low-band audio signal and the basic audio signal.

The narrow-band layer 910 includes information on the low-band signal of the wide-band audio signal encoded by the low-band encoder 510 of FIG. 5A, and is located at a first bit portion of the bit-stream 900. This is to allow the low-band signal of the wide-band audio signal to be restored even if only the narrow-band layer 910 is included in the bit stream 900 and received in the decoding apparatus 450, so as to ensure a basic audio quality of the low-band signal.

The wide-band first layer 920 restores the basic audio signal over the entire high-band, and includes frequency envelope information of a wide-band excited signal, that is, an LPC index 922 of a wide-band excited signal, a gain index 924 of a residual signal (or a linear prediction residual signal) of a high-band signal, and a frequency phase index 926 of a frequency phase at the least harmonic position which has been quantized with priority by the frequency phase quantizer 610. The LPC index 922 corresponds to the second index signal IN2, and the gain index 924 and the frequency phase index 926 correspond to portions of the second index signal IN2 and the third index signal IN3, respectively.

The expansion layer 930 is provided to the bit steam 900 such that high-band frequency information 940 precedes low-band frequency information 950 in the bit-stream 900. This is because the low-band signal can be restored through the narrow-band layer 910 using the narrow-band layer 910, and the low-band frequency (magnitude and phase) information is used to generate an expanded audio signal having a higher layer than the restored low-band signal according to the narrow-band layer 910.

Further, the high-band and low-band frequency information 940 and 950 are provided to the bit stream 900 such that frequency phase information 942 and 952 precede frequency magnitude information 944 and 954 in the bit-stream 900. This is because the linear prediction residual signal cannot be restored without the frequency phase information 942 and 952 even if the frequency magnitude information 944 and 954 are present. However, if only the frequency phase information 942 and 952 are received from the decoding apparatus 450, the linear prediction residual signal can be restored by estimating an approximate frequency magnitude when the gain index 924 of the residual signal restored by the wide-band first layer 920, that is, frequency power information, is used.

The frequency magnitude and phase of the residual signal are dequantized (obtained) using the frequency magnitude and phase information 924, 944, 952, and 944 by analyzing a frequency envelope of the wide-band excited signal according to a frequency envelope magnitude in descending order, so that information on a frequency having a large envelope magnitude is placed at an upper bit of the bit-stream 900, and information on a frequency having a small envelope magnitude is placed at a lower bit of the bit-stream 900. As a result, the wide-band audio signal can be effectively restored by using a less number of bits.

The high-band frequency information 940 may further include a high frequency energy index 946 in addition to the frequency magnitude and phase information 942 and 944. As described above, if only information on the wide-band excited signal down-sampled to 12.8 kHz is encoded, frequency information on the wide-band signal of 12.8 kHz or higher is lost in the frequency domain. In order to compensate for this, the high frequency energy index 946 is obtained from the fourth index signal IN4 when the high frequency energy encoder 536 encodes high frequency energy information of 12.8 kHz or higher. According to another embodiment of the present general inventive concept, if the 16 kHz wide-band excited signal is not down-sampled, the high frequency energy index 946 may not be included. Here, although the present embodiment uses 8 kHz (KHz), 12.8 kHz (KHz), and 16 kHz (KHz) in the method of encoding the wide-band audio signal, the present general inventive concept is not limited thereto. Other frequency ranges can be used in the method of encoding the wide-band audio signal.

FIG. 5B is a block diagram illustrating the decoding apparatus 450 according to an embodiment of the present general inventive concept. Now, an operation of a hierarchical decoding apparatus according to an embodiment of the present invention will be described with reference to FIGS. 4 and 5B.

The decoding apparatus 450 includes a bit dividing unit (demultiplexer) 560, a low-band decoder 570, a third over-sampler 572, a frequency dequantizer 594, a frequency/time converter 592, a linear prediction synthesizer 580, a second over-sampler 582, a first adder 584, a second adder 586, a high frequency generator 588, a first post-processor 574, and a second post-processor 576. The bit dividing unit 560 and terminals for fifth, sixth, seventh, and eighth index signals IN5, IN6, IN7, and IN8 corresponding to the first, second, third, and fourth index signals IN1, IN2, IN3, and IN4, respectively, may constitute the bit depacking unit 460 of FIG. 4.

First, when a bit-steam of a scalably encoded wide-band audio signal is received, the bit dividing unit 560 divides the received bit-stream by depacking the divided bit stream for each of a plurality of layers according to signals of the narrow-band layer 910, the wide-band first layer 920, and the expensing layer 930 of FIG. 9. The narrow-band layer 910 includes information on the low-band signal. The wide-band first layer 920 includes information on the frequency envelope of the wide-band excited signal, the gain of the linear prediction residual signal, and the frequency phase at the harmonic position of the linear prediction residual signal. The expansion layer 930 includes information on the frequency phase of the linear prediction residual signal at a position other than the harmonic position, the frequency magnitude of the linear prediction residual signal, and the high frequency energy (gain).

The low-band decoder 570 decodes the narrow-band layer 910 divided and transmitted from the bit dividing unit 560, and restores the low-band signal using the fifth index signal IN5. If the decoding apparatus 450 receives only the narrow-band layer 910 from the bit-stream 900 transmitted from the encoding apparatus 400, only the low-band signal having the least audio quality restored by the low-band encoder 510 may be restored. It is possible that the restored low-band signal may be output after being subjected to a post-process operation by the first post-processor 574.

If only a part of the bit-stream 900 formed in a layered manner is received, the frequency decoder 490 restores the linear prediction residual signal by using the only part of layers included in the received bit-stream 900. First, the layers for frequency information on the linear prediction residual signal divided by the bit dividing unit 560 are decoded, and a frequency magnitude and phase of the linear prediction residual signal is restored. If only frequency phase information at the harmonic position of the linear prediction residual signal is received, the frequency magnitude is estimated by using gain information of the linear prediction residual signal, and the least linear prediction residual signal is restored by using the received frequency phase information at the harmonic position and the estimated linear prediction residual signal.

When the expansion layer 930 is further included in the bit-stream 900 transmitted from the encoding apparatus 400, the linear prediction residual signal is restored by using frequency information of the linear prediction residual signal included in the received expansion layer 930. According to the present embodiment, since the frequency phase information 942 or 952 precedes the frequency magnitude information 944 or 954, the frequency magnitude information 944 or 954 cannot be transmitted and received prior to the frequency phase information 942 or 952. In addition, since the high-band frequency information 940 precedes the low-band frequency information 950, the high-band frequency information 940 cannot be transmitted prior to the low-band frequency information 950. Therefore, the linear prediction residual signal of a high band can be firstly restored according to the high-band frequency information 940, and when the bit-stream further includes the low-band frequency information 950, the linear prediction residual signal of a low band can be gradually restored. Accordingly, the apparatus and method of scalably encoding/decoding are provided such that the wide-band audio signal can be encoded and/or decoded into various layers, thereby supporting scalability.

The information on the frequency magnitude and phase of the linear prediction residual signal is dequantized using the seventh index signal IN7 by the frequency dequantizer 594, converted into a linear prediction residual signal in the time domain via the frequency/time converter 592, and input to the linear prediction synthesizer 580.

According to the present embodiment, since the time/frequency converter 532 uses a fast Fourier transform (FFT), it is possible that the frequency/time converter 592 uses an inverse fast Fourier transform (IFFT). If the encoding apparatus 400 uses another time/frequency conversion method, the decoding apparatus 450 may use a corresponding frequency/time conversion method used in the encoding apparatus 400.

The linear prediction synthesizer 580 restores frequency envelope information by decoding the wide-band first layer 920. That is, the LPC information 922 of the wide-band first layer 920 is decoded, and the LPC encoded by the linear prediction analyzer 520 of the encoding apparatus 400 is restored using the sixth index signal IN6. Further, the linear prediction synthesizer 580 performs a linear prediction synthesis by using the restored LPC. That is, the wide-band exited signal is restored by using the linear prediction residual signal input from the frequency/time converter 592 and the restored frequency envelope information. According to the present embodiment illustrated in FIG. 5A, a 16 kHz wide-band excited signal is down-sampled to 12.8 kHz by the encoding apparatus 400. When the result thereof is transmitted, the 12.8 kHz wide-band excited signal is restored by the linear prediction synthesizer 580.

In this case, the second over-sampler 582 over-samples the restored 12.8 kHz wide-band excited signal. As described above with reference to the high frequency energy encoder 536 of FIG. 5A, in order to compensate for the high frequency signal of 12.8 kHz or higher which has been lost when the 16 kHz wide-band excited signal is down-sampled to 12.8 kHz by the second down-sampler 518, the encoding apparatus 400 allows the high frequency energy encoder 536 to calculate the 12.8 kHz high frequency signal so as to be quantized and transmitted to the decoding apparatus 450.

The high frequency generator 588 generates a 16 kHz pseudo signal by using a random number generated by a random number generator through linear prediction synthesis. After extracting only a high frequency component of 12.8 kHz or more from the generated 16 kHz pseudo signal using a high-band pass filter, the high frequency signal of 12.8 kHz or higher is generated by multiplying the received high frequency energy index, that is, the high frequency energy index 946, to the information 942 or 944. However, if the high frequency energy index 946 corresponding to the fourth index signal IN4 or the eighth index signal IN8 is not received through the bit-stream 900, the high frequency energy index 946 can be estimated through the wide-band excited signal restored by the linear prediction synthesizer 580 and a frequency slope thereof.

The second adder 586 synthesizes a 12.8 kHz high frequency signal restored by the high frequency generator 588 and a 12.8 kHz wide-band excited signal over-sampled to 16 kHz by the second over-sampler 582, and restores the 16 kHz wide-band excited signal.

The third over-sampler 572 over-samples the low-band audio signal of 8 kHz restored by the low-band decoder 570 to obtain a signal of 16 kHz, and converts a 16 kHz low-band audio signal.

The first adder 584 synthesizes the 16 kHz low-band audio signal generated by the third over-sampler 572 and the 16 kHz wide-band excited signal generated by the second adder 586, and restores a lastly synthesized wide-band audio signal.

In order to obtain a further clear audio signal, the lastly synthesized wide-band audio signal may be subjected to the post-processing operation through the second post-processor 576.

The post-processing operation performed by the first post-processor 574 and the second post-processor 576 may include a formant post-process filtering process and a gain value compensation process which are well-known. In the formant post-process filtering process, an audio signal is further clarified by emphasizing only a formant component of the audio signal. In the gain value compensation process, an energy value that has been lost in the formant post-process filtering process is compensated for.

FIGS. 7C and 7D are flowcharts illustrating a hierarchical decoding method according to an embodiment of the present general inventive concept. Now, the hierarchical decoding method according to the present embodiment will be described with reference to FIGS. 4, 5A, 5B, 7C, and 7D.

In operation 745, the decoding apparatus 450 receives the bit-stream 900 transmitted from the encoding apparatus 400, and scalably divides the bit-stream 900. If the bit-stream 900 received according to the present embodiment is constructed as illustrated in FIG. 9, the received bit-stream 900 can be divided into the narrow-band layer 910, the wide-band first layer 920, and the expansion layer 930. The wide-band first layer 920 can be divided into the LPC index 922, the gain index 924 of the linear prediction residual signal, and the frequency phase index 926 of the audio signal at the harmonic position. The expansion layer 930 can be divided into the high-band frequency phase index 942 of the linear prediction residual signal, the high-band frequency magnitude index 944, the low-band frequency phase index 952, and the low-band frequency magnitude index 954, and the high frequency energy index 946. However, according to an environment of a network channel and a transmission rate of a bit-stream, the received bit-stream 900 may include different layers. Further, the decoding apparatus 450 may scalably restore the wide-band audio signal by using only information included in the received bit-stream 900.

In operation 750, the decoding apparatus 450 decodes the narrow-band layer 910 so as to restore an 8 kHz low-band audio signal, and over-samples the restored 8 kHz low-band audio signal to obtain a 16 kHz low-band audio signal.

In operation 755, the decoding apparatus 450 decodes the gain index 924 of the linear prediction residual signal and the frequency phase index 926 at the harmonic position included in the wide-band first layer 920, and then restores the expansion layer 930, thereby restoring information on the frequency magnitude and phase, and the gain of the linear prediction residual signal. In this case, the restored amount of information on the frequency magnitude and phase of the linear prediction residual signal varies depending on the amount of frequency information on the linear prediction residual signal included in the bit-stream 900 received in operation 745.

In operation 760, the decoding apparatus 450 converts information on the frequency magnitude and phase, and the gain into a linear prediction residual signal in the time domain. Frequency information on the linear prediction residual signal restored in operation 755 may vary depending on signals or layers included in the bit stream 900. Thus, in operation 760, the linear prediction residual signal is scalably restored by using only the information restored in operation 755.

In operation 765, the decoding apparatus 450 decodes the LPC index 922 included in the wide-band first layer 920, and then restores information on the frequency envelope of the wide-band excited signal of 12.8 kHz.

In operation 770, the decoding apparatus 450 restores the 12.8 kHz wide-band excited signal by using the linear prediction residual signal restored in operation 760 and the information on the frequency envelope of the 12.8 kHz wide-band excited signal restored in operation 765, and over-samples the restored 12.8 kHz wide-band excited signal to obtain a 16 kHz signal.

In operation 755, the decoding apparatus 450 decodes the high frequency energy index or the high frequency gain index 924 included in the wide-band first layer 920, and restores a high frequency signal that is a wide-band audio signal of 12.8 kHz or higher.

In operation 780, the decoding apparatus 450 synthesizes the wide-band excited signal over-sampled to 16 kHz in operation 770 and the high frequency signal restored in operation 775, and restores the 16 kHz wide-band excited signal.

In operation 785, the decoding apparatus 450 synthesizes the wide-band excited signal over-sampled to 16 kHz in operation 770 and the low-band audio signal restored in operation 750, and restores the 16 kHz wide-band excited signal.

In an encoding and/or decoding method according to an embodiment of the present general inventive concept, when the bit-stream 900 is scalably formed by encoding a wide-band audio signal, the wide-band first layer 920 capable of restoring a basic signal over the entire high-band is provided, and the wide-band expansion layer 930 is provided by scalably packing frequency information on a linear prediction residual signal according to an auditory sensitivity so that the audio signal can be restored with high fidelity even at a low bit-rate. Therefore, even if the audio signal is transmitted at a low bit-rate due to a network condition or a limit in a transmission rate of a receiving end, the audio signal can be restored with high fidelity, thereby supporting scalability capable of scalably restoring the audio signal.

Accordingly, since frequency information on a wide-band excited signal is scalably encoded/decoded, a wide-band first layer can be provided in which basic information on a high-band audio signal is encoded, and a wide-band expansion layer having a plurality of layers is provided by scalably encoding the frequency information on the wide-band excited signal based on an auditory sensitivity. Therefore, a basic audio signal over the entire high-band can be restored even at a low bit-rate. Furthermore, a fine granularity scalable (FGS) function can be supported since the encoded audio signal includes a plurality of layers. In addition, since a low-band audio signal is encoded/decoded such that it can be restored by using a narrow-band layer, the restored audio signal can maintain a basic audio quality.

The invention can also be embodied as computer readable codes on a computer readable recording medium. The computer readable recording medium is any data storage device that can store data which can be thereafter read by a computer system. Examples of the computer readable recording medium include read-only memory (ROM), random-access memory (RAM), CD-ROMs, magnetic tapes, floppy disks, optical data storage devices, and carrier waves (such as data transmission through the Internet).

The computer readable recording medium can also be distributed over network coupled computer systems so that the computer readable code is stored and executed in a distributed fashion. Also, functional programs, codes, and code segments for accomplishing the present invention can be easily construed by programmers skilled in the art to which the present invention pertains. Accordingly, the encoding method or the decoding method illustrated in FIGS. 7A through 8 can be stored in the computer readable recording medium as the computer readable codes.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A hierarchical encoding method comprising:
encoding a specific band signal included in an input signal;
encoding a frequency envelope of an excited signal in which the encoded specific band signal is removed from the input signal;
encoding a residual signal in which the encoded frequency envelope is removed from the excited signal; and
forming a bit-stream by scalably packing the encoded specific band signal, frequency envelop, and residual signal.

2. The method of claim 1, wherein the forming of the bit stream comprises packing the encoded specific band signal into a narrow-band layer, the encoded frequency envelope of the excited signal and a result obtained by encoding basic frequency information of the residual signal into a wide-band first layer, and frequency information other than the basic frequency information of the residual signal into a wide-band expansion layer.

3. The method of claim 1, wherein the specific band signal is in a band below a specific frequency of the input signal.

4. The method of claim 1, wherein the encoding of the residual signal comprises encoding frequency information of the residual signal.

5. The method of claim 4, wherein the encoding of the frequency information of the residual signal comprises encoding a gain, a frequency magnitude, and/or a frequency phase of the residual signal.

6. The method of claim 4, wherein the frequency information of the residual signal comprises information on a frequency phase of the residual signal, and the encoding of the residual signal comprises:
detecting a harmonic position of the input signal;
encoding the frequency phase at the detected harmonic position, and
encoding other frequency phases excluding the encoded frequency phase.

7. The method of claim 6, wherein the encoding of the other frequency phases comprises:
analyzing a magnitude of a frequency envelope of the excited signal; and
encoding the other frequency phases so that information on a phase of a frequency having a large analyzed magnitude is located in an upper bit in the bit-stream.

8. The method of claim 4, wherein the frequency information of the residual signal comprises a frequency magnitude of the residual signal, and the encoding of the residual signal comprises:
analyzing a magnitude of a frequency envelope of the excited signal; and
encoding the frequency magnitude so that information on a phase of a frequency having a large analyzed magnitude is located in an upper bit in the bit-stream.

9. The method of claim 4, wherein the frequency information on the residual signal comprises a frequency magnitude of the residual signal, and the encoding of the residual signal comprises:
dividing a frequency band constituting any frame into a plurality of sub-bands, and calculating and quantizing a frequency power for each divided sub-band; and
normalizing a frequency magnitude by using the quantized frequency power, and quantizing the normalized frequency magnitude.

10. The method of claim 9, wherein the normalizing of the frequency magnitude comprises quantizing only a part of the normalized frequency magnitude, and quantizing other non-quantized frequency magnitudes of the normalized frequency magnitude by interpolating the quantized frequency magnitude.

11. The method of claim 4, wherein the frequency information of the residual signal comprises the frequency magnitude of the residual signal, and the encoding of the residual signal comprises quantizing a portion of the frequency magnitude if one frame of the input signal is composed of a plurality of sub-frames, and quantizing frequency magnitudes of the non-quantized sub-frames by interpolating the frequency magnitude of the quantized sub-frame.

12. The method of claim 1, wherein the forming of the bit stream comprises:
forming a narrow-band layer using the encoded specific band signal;
forming a wide-band first layer using the encoded frequency envelope, a gain of the residual signal, and/or a frequency phase at a harmonic position; and
forming a wide-band expansion layer using the encoded frequency magnitude and/or the other frequency phases.

13. The method of claim 12, wherein the forming of the wide-band expansion layer comprises forming the wide-band expansion layer such that information on the encoded frequency magnitude and frequency phases included in other bands except for the specific band precedes information on the encoded frequency magnitude and the other frequency phases included in the specific band in a bit-steam.

14. The method of claim 13, wherein the forming of the wide-band expansion layer comprises forming the wide-band expansion layer such that information on the other frequency phases precedes information on the frequency magnitude in the bit-stream.

15. A hierarchical encoding method comprising:
encoding a specific band signal included in an input signal;
encoding a frequency envelope of an excited signal obtained by down-sampling a signal in which the encoded specific band signal is removed from the input signal;
encoding a residual signal in which the encoded frequency envelope of the exited signal is removed from the excited signal;
encoding a gain of a high frequency signal obtained by removing the excited signal from the signal in which the encoded specific band signal is removed from the input signal; and
forming a bit-stream by scalably packing the encoded specific band signal, frequency envelop, residual signal, and gain of the high frequency signal.

16. A hierarchical encoding apparatus comprising:
a low-band encoder to encode a specific band signal included in an input signal;
a linear prediction analyzer to encode a frequency envelope of an excited signal in which the encoded specific band signal is removed from the input signal;
a frequency encoder to encode a residual signal in which the encoded frequency envelope is removed from the excited signal; and
a bit packing unit to form a bit-stream by scalably packing the encoding results of the low-band encoder, the linear prediction analyzer, and the frequency encoder.

17. A computer-readable medium having embodied thereon a computer program for executing a hierarchical encoding method, the method comprising:
encoding a specific band signal included in an input signal;
encoding a frequency envelope of an excited signal in which the encoded specific band signal is removed from the input signal;
encoding a residual signal in which the encoded frequency envelope is removed from the excited signal; and
forming a bit-stream by scalably packing the encoded specific band signal, frequency envelop, and residual signal.

18. A hierarchical decoding method comprising:
dividing a received bit-stream by depacking the bit stream for each of a plurality of layers;
restoring a specific band signal included in an input signal, a frequency envelope of an excited signal in which the encoded specific band signal is removed from the input signal, and a residual signal in which the encoded frequency envelope is removed from the excited signal, by decoding each of the divided layers;
restoring the excited signal according to the frequency envelope of the restored excited signal and the restored residual signal; and
restoring the input signal by synthesizing the restored excited signal and the specific band signal of the input signal.

19. The method of claim 18, wherein the specific band signal is in a band below a specific frequency of the input signal.

20. The method of claim 18, wherein the dividing of the received bit-stream comprises depacking the received bit-stream for each of the layers into a narrow-band layer comprising a result obtained by encoding the specific band signal included in the input signal, a wide-band first layer comprising a result obtained by encoding the frequency envelope of the excited signal and a result obtained by encoding basic frequency information of the residual signal, and a wide-band expansion layer comprising frequency information other than the basic frequency information of the residual signal.

21. The method of claim 18, wherein the encoding of the frequency envelope comprises:
restoring frequency information of the residual signal by decoding each of the divided layers; and
restoring the residual signal according to the restored frequency information.

22. The method of claim 21, wherein the frequency information of the residual signal comprises a gain, a frequency magnitude, and/or a frequency phase of the residual signal.

23. The method of claim 21, wherein the frequency information of the residual signal comprises information on a frequency phase of the residual signal, and the restoring of the frequency information comprises:
restoring information on a frequency phase of the input signal at a harmonic position from the frequency phase of the residual signal.

24. The method of claim 23, wherein the restoring of the frequency information further comprises restoring frequency phases other than the frequency phase of the input signal at the harmonic position.

25. The method of claim 24, wherein the restoring of the frequency information comprises:
analyzing a magnitude of the restored frequency envelope; and
restoring the other frequency phases according to the analyzed magnitude in descending order.

26. The method of claim 21, wherein the frequency information of the residual signal comprises information on a frequency magnitude of the residual signal, and the restoring of the frequency information comprises:
analyzing a magnitude of the restored frequency envelope; and
restoring the frequency magnitude according to the analyzed magnitude in descending order.

27. The method of claim 18, wherein the received bit-stream comprises a narrow-band layer comprising a result obtained by encoding the specific band signal included in the input signal, a wide-band first layer comprising a result obtained by encoding the frequency envelope of the excited signal and a result obtained by encoding basic frequency information of the residual signal, and/or a wide-band expansion layer comprising the frequency information other than the basic frequency information of the residual signal.

28. A hierarchical decoding method comprising:
dividing a received bit-stream by depacking the bit stream for each of a plurality of layers;
restoring a specific band signal included in an input signal, a frequency envelope of an excited signal which is obtained by down-sampling a signal in which the encoded specific band signal is removed from the input signal, a residual signal in which the encoded frequency envelope of the excited signal is removed from the excited signal, and a gain of a high frequency signal which is obtained by removing the down-sampled excited signal from the signal in which the encoded specific band signal is removed from the input signal, by decoding each of the divided layers;
restoring the excited signal by using the frequency envelope of the restored excited signal and the restored residual signal;
restoring the high frequency signal by using the gain of the high frequency signal; and
restoring the input signal by synthesizing a signal obtained by over-sampling the restored excited signal, and the restored high frequency signal, and the specific band signal included in the restored input signal.

29. A hierarchical decoding apparatus comprising:
a bit depacking unit to divide a received bit-stream by depacking the bit stream for each of a plurality of layers;
a band decoder to restore a specific band signal included in an input signal by decoding the divided layers;
a frequency decoder to restore a frequency envelope of an excited signal in which the encoded specific band signal is removed from the input signal, and a residual signal in which the encoded frequency envelope is removed from the excited signal, by decoding each of the divided layers;
a linear prediction synthesizer to restore the frequency envelope of the excited signal by decoding the divided layers, and to synthesize the excited signal by using the restored frequency envelope and the restored residual signal; and
a synthesizer to restore the input signal by using the specific band signal of the restored input signal and the restored excited signal.

30. A computer-readable medium having embodied thereon a computer program for executing a hierarchical decoding method, the method comprising:
dividing a received bit-stream by depacking the bit stream for each of a plurality of layers;
restoring a specific band signal included in an input signal, a frequency envelope of an excited signal in which the encoded specific band signal is removed from the input signal, and a residual signal in which the encoded frequency envelope is removed from the excited signal, by decoding each of the divided layers;
restoring the excited signal by using the frequency envelope of the restored excited signal and the restored residual signal; and
restoring the input signal by synthesizing the restored excited signal and the specific band signal of the input signal.
